(19) United States
(12) Patent Application Publication
(10) Pub. No.: US 2012/0107748 A1
(43) Pub. Date: May 3, 2012

(54) DRAWING APPARATUS AND METHOD OF MANUFACTURING ARTICLE

(75) Inventor: Tomoyuki Morita, Utsunomiya-shi (JP)

(73) Assignee: CANON KABUSHIKI KAISHA, Tokyo (JP)

(21) Appl. No.: 13/281,797

(22) Filed: Oct. 26, 2011

(30) Foreign Application Priority Data
Oct. 29, 2010 (JP) 2010-244366

(51) Int. Cl. G03F 7/20; G21K 5/00

(52) U.S. Cl. 430/325; 250/453.11

(57) ABSTRACT

A drawing apparatus, that performs drawing on a substrate using an array of charged particle beams, includes a projection system and a controller. The projection system is configured such that the array includes a plurality of sub arrays arranged discretely on the substrate with a space between the sub arrays in a predetermined direction, and a first width of the space in the predetermined direction is n1/n2 times (each of n1 and n2 is a positive integer) a second width of the sub array in the predetermined direction. The controller is configured to control the projection system and a driving mechanism such that drawing is performed in order with the plurality of sub arrays for [n1+n2] sets of drawing regions that are shifted from one another by as much as [1/n2] times the first width so that drawing is performed for a shot region on the substrate.

### BACKGROUND OF THE INVENTION

1. Field of the Invention

Embodiments of the present invention relate to a drawing apparatus that performs drawing on a substrate using an array of charged particle beams, and a method of manufacturing an article using the drawing apparatus.

2. Description of the Related Art

As a drawing apparatus for use in manufacture of devices such as a semiconductor integrated circuit (IC) or the like, a drawing apparatus has been known which performs drawing on a substrate using a plurality of charged particle beams (an array of charged particle beams) (see Japanese Patent Application Laid-Open No. 9-7538).

In order to improve throughput, such a drawing apparatus increases the number of charged particle beams by widening a field of view. In this case, it is difficult to cope with issues of aberration of an optical system for projecting the charged particle beams on the substrate, manufacturing errors, and temporal changes. For this reason, there is discussed a drawing apparatus including a deflector that deflects charged particle beams for each sub array, in which the sub arrays constitute an array of charged particle beams (see Japanese Patent No. 3647128)

In the case of using a deflector that deflects charged particle beams for each sub array as discussed in Japanese Patent No. 3647128, the sub arrays are arranged with a space disposed between them. The drawing apparatus is not limited to this structure. More specifically, in some optical elements (a lens, a deflector, or the like) used for treating charged particle beams, spacers or joists are installed at predetermined intervals to reduce the deflection of a thin plate such as an electrode included therein. In this way, for some reasons, an array of charged particle beams is configured such that sub arrays of charged particle beams are arranged with a space disposed between the sub arrays. This space is desired to be small in size in terms of effective use of charged particle beams emitted from a charged particle beam source. However, there is a natural limit to reduction in the size of the space due to the restriction that the objective, provision of space, should be achieved. Meanwhile, the sub array is desired to be large in size in terms of effective use of the charged particle beams emitted from a charged particle beam source. However, owing to the same restriction as above, there is also a limit to an increase in the size of the sub array. Accordingly, the sizes of the sub array and space can be determined taking the restriction set forth above into consideration.

However, it is not sure that the sizes of the sub array and space determined in that way can lead to the effective use of the sub arrays used to perform drawing on the substrate. For example, after completion of drawing performed on a substrate using a plurality of sub arrays, when drawing is performed for a region of the substrate corresponding to the space that was not subjected to the drawing before, if that region is narrower than a drawing region of a sub array, not all of the charged particle beams in the sub array can be used for drawing. In that case, the charged particle beams emitted from a charged particle beam source cannot be effectively used.

### SUMMARY OF THE INVENTION

Embodiments of the present invention are directed to a drawing apparatus that is advantageous in effective use of charged particle beams of a sub array.

According to an aspect of an embodiment of the present invention, a drawing apparatus that performs drawing on a substrate with an array of charged particle beams, includes: a stage configured to hold the substrate; a projection system configured to project the array onto the substrate held by the stage; a driving mechanism configured to move at least one of the stage and the projection system relative to the other in a predetermined direction to change a drawing region on the substrate; and a controller, wherein the projection system is configured such that the array includes a plurality of sub arrays arranged discretely on the substrate with a space between the sub arrays in the predetermined direction, and a width (first width) of the space in the predetermined direction is n1/n2 times (each of n1 and n2 is a positive integer) a width (second width) of the sub array in the predetermined direction, and wherein the controller is configured to control the projection system and the driving mechanism such that drawing is performed in order with the plurality of sub arrays for [n1n2] sets of drawing regions that are shifted from one another by as much as [1/n2] times the first width so that drawing is performed for a shot region on the substrate.

According to an exemplary embodiment of the present invention, it is possible to provide, for example, a drawing apparatus advantageous in effective use of charged particle beams of a sub array.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a diagram illustrating an example of the structure of a drawing apparatus according to a first exemplary embodiment of the present invention.

FIG. 2 is a diagram illustrating an exemplary arrangement of sub arrays according to the first exemplary embodiment.

FIGS. 3A and 3B are diagrams illustrating an example of multiple sets of drawing regions in a shot region for which drawing is consecutively performed set by set using a sub array.

FIG. 4 is a diagram illustrating an example of a form in which drawing is performed for a plurality of shot regions on a substrate.

FIG. 5 is a diagram illustrating an exemplary arrangement of beams inside a sub array.

FIG. 6 is a diagram illustrating another exemplary arrangement of beams inside a sub array.

FIG. 7 is a diagram illustrating an exemplary arrangement of sub arrays according to a second exemplary embodiment of the present invention.

FIGS. 8A and 8B are diagrams illustrating an example of multiple sets of drawing regions in a shot region for which drawing is consecutively performed set by set using a sub array.

### DESCRIPTION OF THE EMBODIMENTS

Various exemplary embodiments, features, and aspects of the invention will be described in detail below with reference to the drawings.

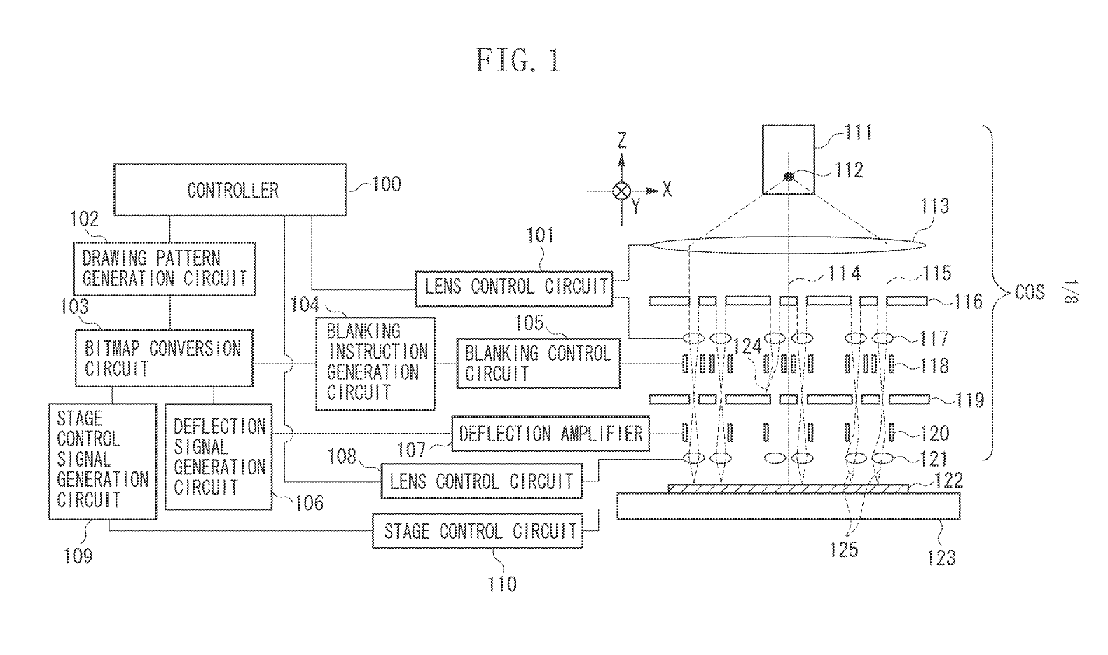

FIG. 1 is a diagram illustrating an example of the structure of a drawing apparatus according to a first exemplary embodiment of the present invention. FIG. 1 illustrates an example of the structure of a drawing apparatus that performs drawing on a substrate using charged particle beams. In the present exemplary embodiment, electron beams are used as charged particle beams. However, other types of charged particle beams such as ion beams may replace the electron beams. Referring to FIG. 1, a projection system COS irradiates a substrate held on a stage to be described below with an array of electron beams. An electron beam source (charged particle beam source) 111 forms a crossover 112. Trajectories 114 and 115 of electrons (charge particles) are radiated from the crossover 112. The electrons radiating from the crossover 112 form a parallel beam by the action of a collimator lens 113 that generates at least either an electric field or a magnetic field, or both, and the parallel beam is incident onto an aperture array 116. The electron beam that is incident onto the aperture array 116 is split into a plurality of electron beams to form an array of electron beams (an array of charged particle beams). The aperture array 116, for example, has a plurality of apertures (for example, circular openings) formed to be distributed discretely, regularly in two dimensions. The array of electron beams includes sub arrays of electron beams that are discretely arranged with a predetermined size of space provided between the sub arrays of electron beams. The arrangement of electron beams inside the sub array and the spaces between the sub arrays depend on the arrangement of the apertures in the aperture array 116. The sizes of the sub array and space are determined according to the factors that influence how an array of charged particle beams is configured with sub arrays of charged particle beams. Examples of the factors include the size of a deflector that deflects charged particle beams for each sub array, and the size, interval, and the like of spacers or joists that are installed to reduce the deflection of a thin plate such as an electrode included in an optical element (a lens, a deflector, or the like) of a charged particle beam optical system.

An array of electron beams formed by the aperture array 116 is incident onto an electrostatic lens array 117 including three electrode plates (not illustrated), each having an array of apertures (for example, circular openings) formed therein. At the position where the electrostatic lens array 117 forms the crossover, a blanking deflector array 118, in which an array of openings having the same arrangement as the aperture array 116, is formed. The blanking deflector array 118 individually deflects the electron beams in an electron beam array. The electron beams 124 deflected by the blanking deflector array 118 are stopped by a stopping aperture array 119. In the stopping aperture array 119, an array of openings arranged in the same fashion as the apertures of the aperture array 116 is formed. The blanking deflector array 118 is controlled by a blanking control circuit 105 and individually deflects the respective electron beams for performing a blanking operation beam by beam. The blanking control circuit 105 controls the blanking operation based on a blanking signal generated by a blanking instruction generation circuit 104. A drawing pattern is generated by a drawing pattern generation circuit 102. This drawing pattern is converted into bitmap data by a bitmap conversion circuit 103. The blanking instruction generation circuit 104 generates the blanking signal based on the bitmap data.

The electron beams having passed through the stopping aperture array 119 without being deflected by the blanking deflector array 118 form an image of the crossover 110 on the substrate 122 with the aid of the electrostatic lens array 121. A stage unit 123 includes a movable stage that holds the substrate 122, and an actuator (a drive unit) that moves at least one of the stage and the projection system COS relative to the other in a predetermined direction to change a drawing region on the substrate 122.

A deflector array 120 includes deflectors provided to correspond to sub arrays of electron beams in one-to-one. Each deflector deflects one sub array to move a position 125 of the electron beams inside the sub array on an X-Y plane on the substrate 122. The deflector array 120 is not limited to the structure such that the deflectors correspond to the sub arrays in one-to-one relation. For example, the deflector may be provided for every plural sub arrays or provided for each electron beam. A deflection signal generation circuit 106 generates a deflection signal based on the bitmap data. The deflection amplifier 107 generates a drive signal for driving the deflector array 120 based on the deflection signal generated by the deflection signal generation circuit 106.

The stage unit 123 is controlled by the stage control circuit 110. The stage control circuit 110 controls the positioning of the stage based on the stage control signal generated by the stage control signal generation circuit 109. The stage control signal generation circuit 109 generates a stage control signal based on the bitmap data. The position of the stage is measured by a measuring instrument such as a laser length-measuring instrument (not illustrated), and the result of the measurement is used for the control on the positioning of the stage. During the drawing, the substrate 122 is scanned (main scanned) by the array of the electron beams while the stage is moved (sub scanned). Because of this, the control on the positioning of the stage by the stage control circuit 110, the control of the deflector array 120 by the deflection amplifier 107, and the control on the blanking operation of the blanking deflector array 118 by the blanking control circuit 105 are performed in synchronization with one another. In this way, drawing is performed on the substrate 122 with use of an array of electron beams.

Furthermore, the collimator lens 113 and the electrostatic lens array 117 are controlled by a lens control circuit 101, and the electrostatic lens array 121 is controlled by a lens control circuit 108. In addition, the drawing operation performed by the circuits 101 to 110 is under control of the controller 100.

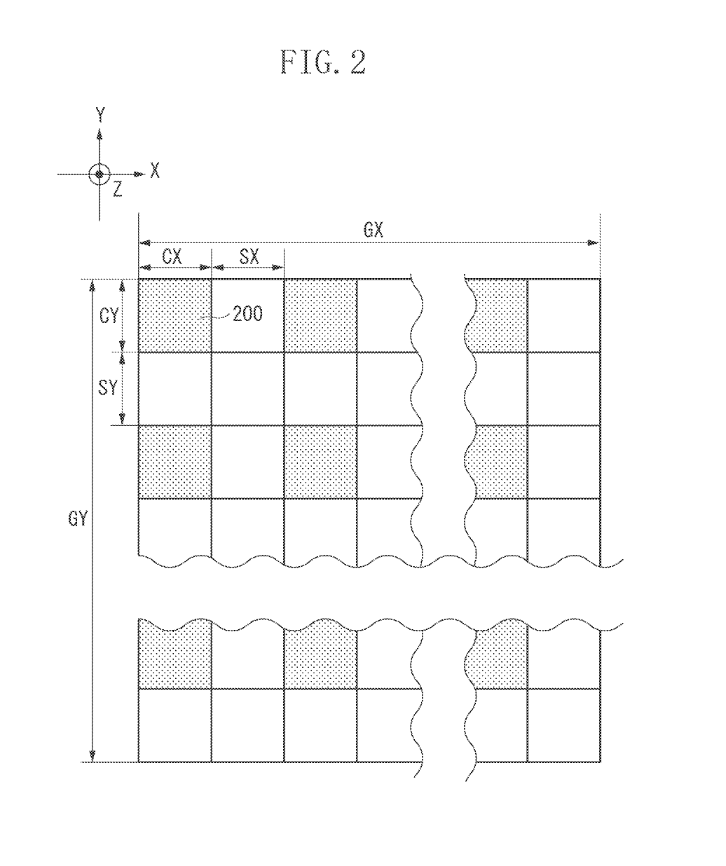

FIG. 2 is a diagram illustrating an example of the arrangement of sub arrays according to the present exemplary embodiment. FIG. 2 illustrates the arrangement of the sub arrays of the electron beams on the substrate 122. The array of the electron beams is laid out such that the sub arrays 200 of electron beams are discretely arranged on the substrate 122 with the specified space between the sub arrays 200 by the aperture array 116 described above. The sub array 200 has a width CX in an X-axis direction and a width CY in a Y-axis direction. The sub arrays 200 are arranged in a matrix with a space having a width SX (in the X-axis direction) and a width SY (in the Y-axis direction) disposed between every adjacent sub arrays. The X-axis direction and the Y-axis direction are two directions intersecting each other. Furthermore, the X-axis direction and Y-axis direction are not necessarily orthogonal to each other but it is sufficient that they are two directions crossing each other. In each axial direction, the width of the space (nominal size; first width) is set to n1/n2 (as for n1 and n2, each is a positive integer, and the values thereof can differ depending on the axis) times the width (nominal size; second width) of the sub array 200. With this kind of multiple sub arrays 200, drawing is performed for a shot region with a width GX (in the X-axis direction) and a width GY (in the Y-axis direction). FIG. 2 illustrates the arrangement of sub arrays in the case of a simple configuration, that is, in the case of n1/n2=1, in other words, SX=CX and SY=CY. Furthermore, when describing the present exemplary embodiment, if being not specifically contradicted, various sizes and dimensions represent nominal values (design values). The formulas (or character expressions) presented in the description of the present exemplary embodiment represent relations between such nominal values.

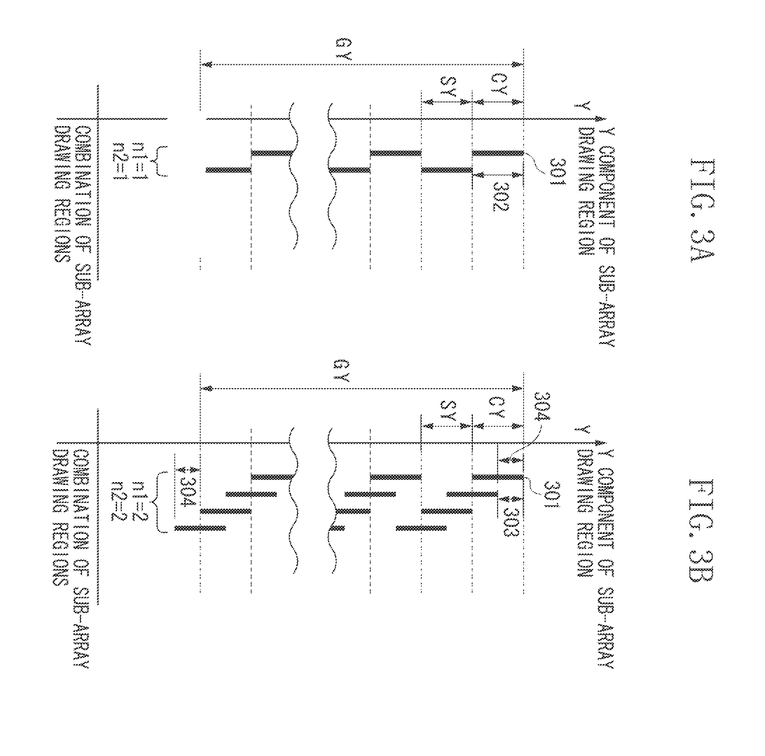

Described next is a form in which drawing is performed for a single shot region using the arrangement of the sub arrays illustrated FIG. 2. For simplicity, the description is based on the assumption that an array of electron beams is split only in a predetermined direction (herein, the Y-axis direction) into a plurality of sub arrays. FIGS. 3A and 3B are diagrams illustrating a shot region in which drawing is performed consecutively for multiple sets of drawing regions, set by set, with use of sub arrays. In FIGS. 3A and 3B, the same components as those in FIG. 2 are denoted by the same reference symbols and the description thereof will not be repeated. First, the width CY in the Y-axis direction of the sub array is the same as a width 301 of a drawing region (a sub array drawing region) for which drawing is performed with use of the sub array 200 in the Y-axis direction. As for the drawing region corresponding to each sub array, the first drawing is performed according to the drawing method to be described below, so that a plurality of regions (for example, three regions indicated by a heavy line in FIG. 3A), each having a width 301, inside a shot region is subjected to drawing. For this case, the drawing is not performed on a region corresponding to the space having the width SY. Subsequently, the plurality of regions having each width 301 are shifted by a distance 302 which is as much as [1/n2] (1/n2=1 in FIG. 3A) times the width CY (the first width) in the Y-axis direction, and the second drawing is performed with use of each sub array of electron beams. With the two times of drawing, drawing for one shot region (having the width GY) is completed. Generally, drawing for one shot region is done in a manner that drawing is consecutively performed using the plurality of sub arrays (a sub array set) for [(1+n1/n2)/(1/n2)]=[n1+n2] sets of sub array drawing regions, set by set, while sequentially shifting the sub arrays in the Y-axis direction by as much as [1/n2] times the width CY. More specifically, the drawing of a partial region, in which an interval between adjacent sub arrays is CY+SY, is achieved by performing drawing for [n1+n2] sets of sub array drawing regions while sequentially shifting a sub array set in the Y-axis direction by as much as 1/n2 times the width CY. When n2 is 2 or more, each set (in FIG. 3, a set indicated by respective heavy lines) of the sub array drawing regions has a region which overlaps another set. In this case, due to consecutive drawings of multiple sets of sub array drawing regions, uniform drawing over a shot region having the width GY is achieved by n2 times of multiple drawing. The order of performing drawing for the multiple sets of the sub array drawing regions may be random, but consecutive drawings in the sub scanning direction of the stage can be performed in terms of throughput.

Specifically, in the case (FIG. 3A) of n1/n2=1 and at the same time n1=n2=1; the number of sets of the sub array drawing regions becomes n1+n2=2, and the shifting amount becomes [1/n2=1] times the width CY. More specifically, for two sets of sub array drawing regions where one set is shifted from the other by the width CY, drawing is performed consecutively set by set with use of a set of sub arrays of electron beams (hereinafter, referred to as a sub array set). In this way, drawing is done uniformly over a shot region having the width GY without performing multiple drawing (multiplicity=n2=1 (time)).

In addition, in the case of n1/n2=1 and at the same time n1=n2=2 (see FIG. 3B); the number of sets of sub array drawing regions becomes n1+n2=4, and the shifting amount becomes [1/n2=½] times the width CY. More specifically, drawing is done uniformly over a shot region having the width GY by multiple drawing (multiplicity=n2=2 (times)) in which drawing is consecutively performed for four sets of sub array drawing regions, set by set, which are shifted from one another by as much as ½ times the width CY using a sub array set. Furthermore, in a case (in the case of n2≧2) in which drawing is performed by multiple drawing, there is generated a region 304 in which multiplicity (the number of times of drawing performed) is insufficient (multiplicity is under n2), and the region 304 has the width as much as [1-1/n2] times the width CY. How drawing for the region 304 is performed will be described below.

The two-dimensional arrangement of sub arrays as illustrated in FIG. 2 can be configured by expanding the way of thinking of the one-dimensional arrangement of sub arrays, in which an array of electron beams is split into a plurality of sub arrays in only the Y-axis direction, described above with reference to FIG. 3. More specifically, the shifting amount of the sub array drawing regions for each axis is [1/n2] times the width of a sub array, the number of sets of the sub array drawing regions becomes the product of the numbers (n1+n2) of sets for each axis, the multiplicity becomes the product of the multiplicities (n2) for each axis. For example, for both of the X-axis and Y-axis, n1=n2=1 in the arrangement of sub arrays of FIG. 2; the shifting amount for the X-axis is [1/n2=1] times the width CX, the shifting amount for the Y-axis is [1/n2=1] times the width CY, the number of sets of sub array drawing regions becomes 2×2=4, and the multiplicity becomes 1×1=1. In the same way, for both of the X-axis and Y-axis, n1=n2=2, the shifting amount for the X-axis is [1/n2=½] times the width CX, the shifting amount for the Y-axis is [1/n2=½] times the width CY, the number of sets of the sub array drawing regions is 4×4=16, and the multiplicity becomes 2×2=4. In the same way, when n1=n2=1 for the X-axis and n1=n2=2 for the Y-axis, the shifting amount for the X-axis is [1/n2=1] times the width CX, the shifting amount for the Y-axis is [1/n2=½] times the width CY, the number of sets of the sub array drawing regions is 2×4=8, and the multiplicity becomes 1×2=2. In this way, at least one of n1 and n2 is different between axes.

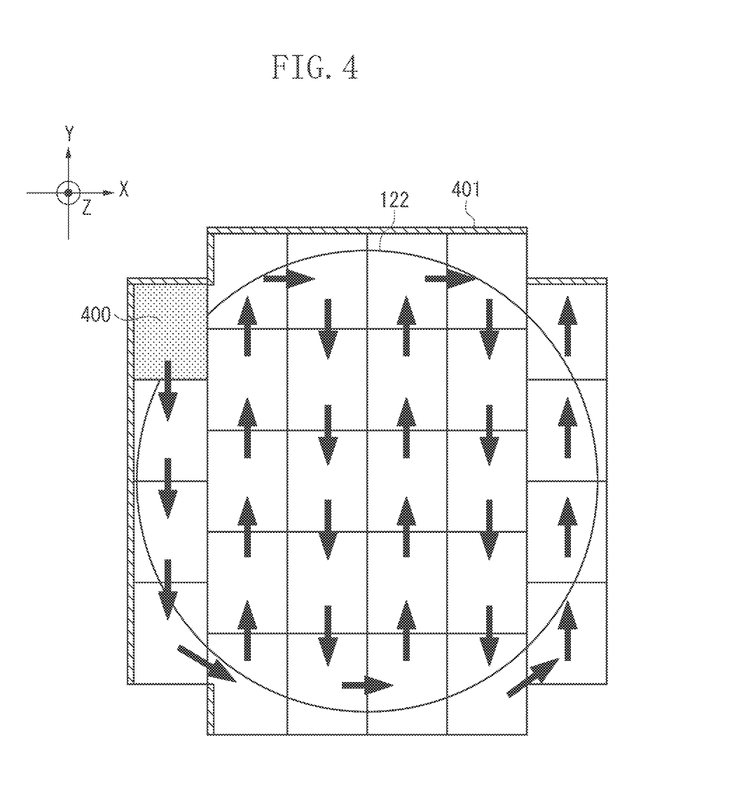

FIG. 4 is a diagram illustrating a form in which drawing is performed for a plurality of shot regions on the substrate 122. Shot regions 400, each having a width GX in the X-axis direction and a width GY in the Y-axis direction, are arranged to be adjacent to each other on the substrate 122. Each time drawing for each shot region is completed, the stage is driven to be stepped, so that the drawing is consecutively performed for a plurality of shot regions in the order illustrated by arrows in FIG. 4.

For the region 304 where the multiplicity is insufficient (the multiplicity is under n2) as described above with reference to FIG. 3B, by arranging the shot regions to be adjacent to each other as illustrated in FIG. 4, drawings for two shot regions which are adjacent to each other are complementarily performed (or compensated). This kind of complementary drawing is allowed for an end portion of a shot region at which a neighboring shot region presents. However, it is not allowed for an end portion of a shot region at which a neighboring shot region does not present. Accordingly, the region 401 where the multiplicity becomes insufficient remains. So, it is desirable to set the arrangement of shot regions for the substrate 122 such that this kind of the region 401 does not overlap an effective region (the effective or usable drawing region; it may be the entire region of the upper surface of the substrate 122) which is set for the substrate 122.

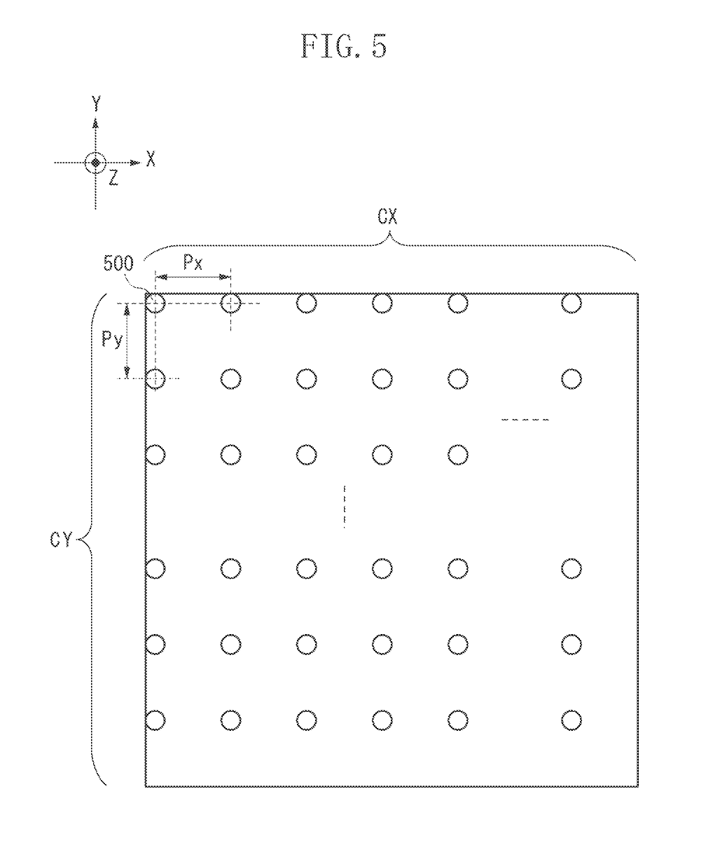

FIG. 5 is a diagram illustrating an example of the arrangement (a rectangular lattice arrangement) of beams inside a sub array on the substrate 122. In FIG. 5, the same components as those in FIG. 2 are denoted by the same reference symbols and the description thereof will not be repeated. The electron beams 500 are arranged in a lattice fashion with an X axial pitch Px and a Y axial pitch Py. The drawing using the plurality of electron beams is performed principally through deflection (main scanning; raster scanning over the pitch Px) of the electron beams by a deflector array 120 in the X-axis direction and principally through movement (sub scanning; scanning over the pitch Py) of the stage in the Y-axis direction. The electron beams are desired to be arranged with a pitch as small as possible. However, since there are mechanical and optical design constraints of the aperture array 116 and the electrostatic lens arrays 117 and 121, the pitch should be normally set to several tens micrometers. On the other hand, the deflection amount of the electron beam on the substrate by the deflector array 120 is limited to several micrometers smaller than the pitch of the electron beams due to the factor such as deflection aberration that is allowed. For this reason, a region is divided in the X-axis direction, and the raster scanning is performed for each of partial regions resulting from the division of a region in the X-axis direction. The multiple drawing may be performed while drawing is performed on each sub array drawing region. In the description, the X-axis direction and the Y-axis direction are used as a main scanning direction and a sub scanning direction, respectively, but they may be used in an opposite manner.

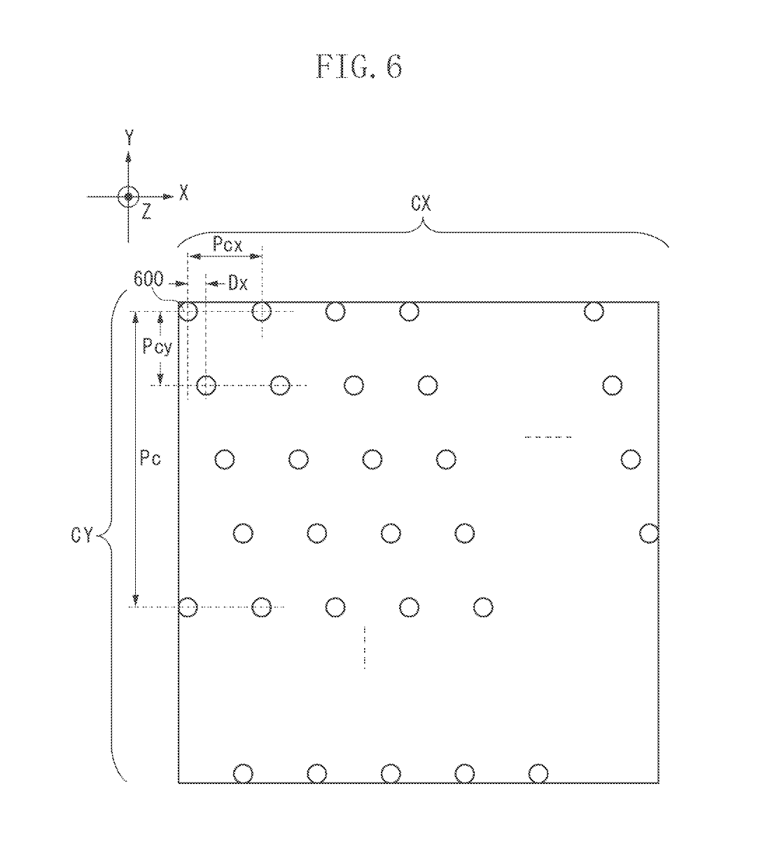

FIG. 6 is a diagram illustrating an example of the arrangement (checkerboard lattice or checkerboard-like lattice arrangement) of beams inside a sub array on the substrate 122. In FIG. 6, the same components as those in FIG. 2 are denoted by the same reference symbols and the description thereof will not be repeated. The charged particle beams 600 are arranged with an X axial pitch Pcx and a Y axial pitch Pcy. Between two columns neighboring with each other at the pitch Pcy, the electron beams are arranged such that they are shifted from one another in the X-axis direction by a distance of Dx, thereby resulting in the checkerboard lattice (checkerboard-like lattice) arrangement. In other words, such an arrangement is obtained by consecutively shifting the arrangement (column) of the electron beams extending in the Y-axis direction by as much as the pitch Pcy in the Y-axis direction and by as much as the distance Dx in the X-axis direction. The distance Dx can be selected to be [1/k] times the pitch Pcx (k is an integer equal to 2 or more). For this case, the position of the electron beams in a column is iterated with a cycle of (Pcx/Dx) columns. When a bundle of electron beams having the width Pc in the Y-axis direction which corresponds to one cycle is defined as one checkerboard lattice (checkerboard-like lattice) block, in the present exemplary embodiment, one sub array may be configured with a plurality of checkerboard lattice blocks which is lined up in the Y-axis direction. FIG. 4 illustrates an example in which one checkerboard lattice block includes four columns of electron beams, but the number of columns of the electron beams which form one checkerboard lattice block is not limited thereto.

The drawing using a plurality of electron beams arranged in this way is performed through deflection (main scanning; raster scanning over the width Dx) of the electron beams principally in the X-axis direction by the deflector array 120 and through movement (sub scanning; scanning over the width Pc) of the stage principally in the Y-axis direction. The width Dx can have a value equal to or smaller than the deflection width of the deflector array 120. With such a setting, the region division in the X-axis direction and the consecutive drawing are not required. Accordingly, such a setting is advantageous in that the number of times of movement (sub scanning operation) of the stage in the Y-axis direction is small, that is, in terms of good throughput.

Furthermore, for the drawing for each sub array drawing region, the multiple drawing may be allowed. When multiple blocks of electron beams, each block being smaller than a sub array such as one checkerboard lattice block illustrated FIG. 6, are arranged in the Y-axis direction to constitute a sub array, the multiple drawing may be performed using repeatability. Specifically, for example, it is possible to perform multiple drawing of M times by performing the movement of the stage in the Y-axis direction (sub scanning) by as much as M times the width Pc of one checkerboard lattice block. The number of checkerboard lattice blocks lined up in the Y-axis direction and the multiplicity M can be set to agree with each other. With such a setting, it is possible to perform drawing for a plurality of sub array drawing regions adjacent to each other by consecutive scanning operations (sub scanning) without operating the stage in a stepwise manner. This is advantageous in terms of improved throughput.

Furthermore, when sub arrays of the checkerboard lattice arrangement, described above, are used, each sub array drawing region is a region having a saw-like boundary which connects shapes having a width corresponding to the Y axial width Pc of one checkerboard lattice block in the boundary (periphery) which extends in the Y-axis direction. In addition, for the multiple drawing which uses the repeatability of the checkerboard lattice blocks, the shot region includes a particular region generated in which the width thereof is (M−1) times the Y axial width Pc and the multiplicity is insufficient (the multiplicity is under M). Concerning the particular region, similar to the exemplary embodiment, described with reference to FIG. 4, in which drawing is performed for a plurality of shot regions on the substrate 122, when multiple shot regions are arranged to be adjacent to one another and are consecutively subjected to drawing, it is possible to make the multiplicity of those regions similar to that of the other regions. In the description, the X-axis direction and the Y-axis direction are used as the main scanning direction and the sub scanning direction, respectively, but they may be used in the opposite manner.

According to the present exemplary embodiment, it is possible to provide a drawing apparatus that is advantageous in terms of effective use of a sub array of charged particle beams.

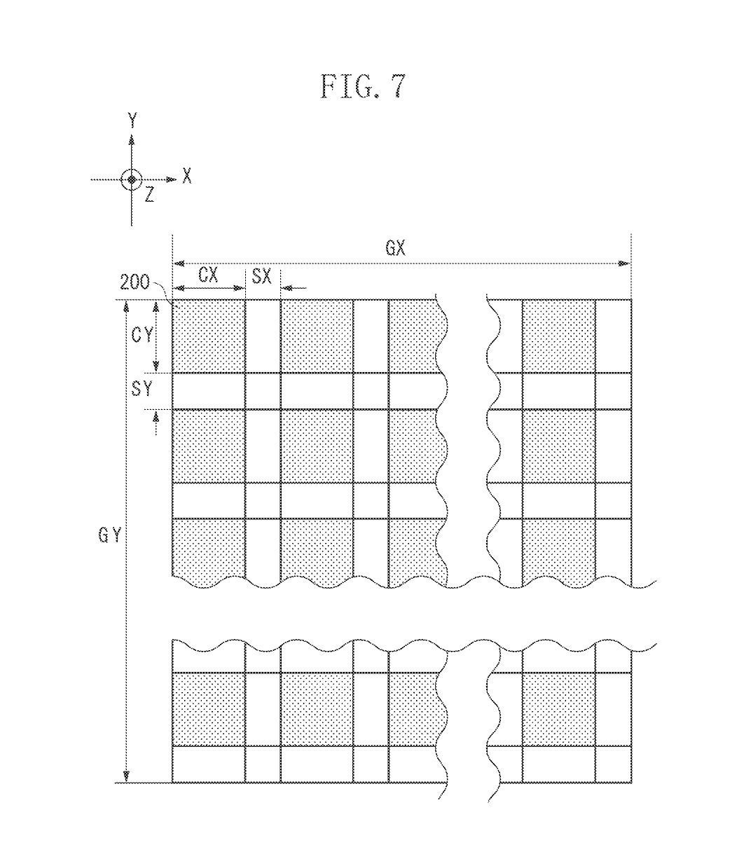

FIG. 7 is a diagram illustrating another example of the arrangement of sub arrays according to a second exemplary embodiment of the present invention. FIG. 7 illustrates the layout of sub arrays of electron beams on a substrate 122. In FIG. 7, the same components same as those in FIG. 2 are denoted by the same reference symbols and the description thereof will not be repeated. The difference in the configuration between the present exemplary embodiment and the first exemplary embodiment will be described. FIG. 7 illustrates n1/n2=½. This case differs from the first exemplary embodiment (see FIG. 2) in that a width of a space between sub arrays is narrower than a width of one sub array. In the present exemplary embodiment, the sub arrays are arranged such that SX=CX/2 and SY=CY/2 are satisfied. When n1/n2<1 is satisfied, a numerical aperture of the aperture array 116 is relatively high as compared to the configuration example of the first exemplary embodiment (n1/n2=1), and the utilization efficiency of the electron beams emitted from the electron beam source is high. In this case, for example, it is possible to increase the number of electron beams in an electron beam array. In addition, in this case, if the numbers of electron beams between the electron beam arrays are the same, the sub array drawing region (a field of view, or, a range in which apertures are arranged in the aperture array 116) becomes narrower, and hence it is possible to reduce the emittance required for the electron beam source.

From this point of view, the sub array arrangement which satisfies n1/n2<1 is desirable.

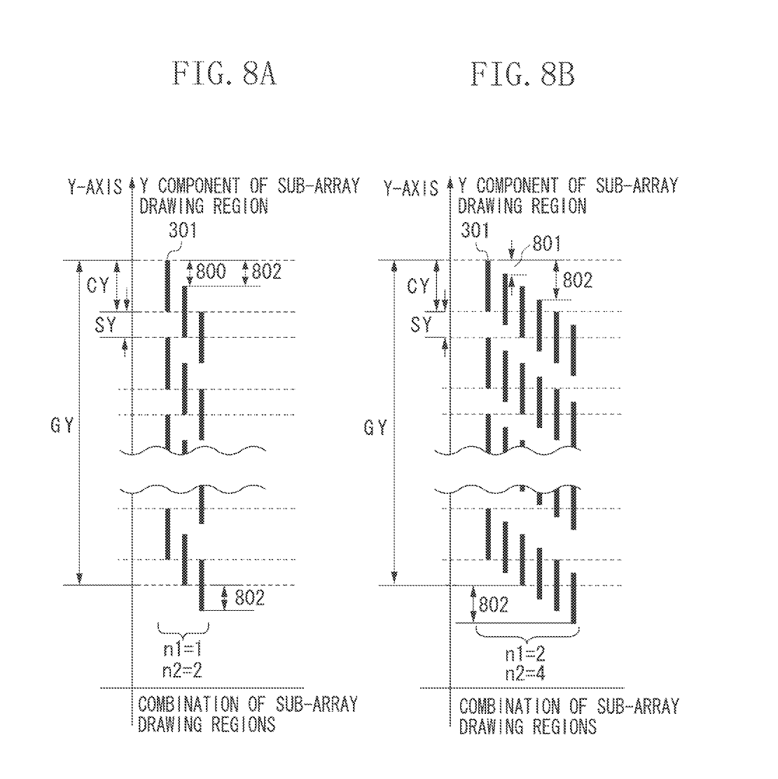

For an exemplary embodiment in which drawing is performed for a shot region using the arrangement of sub arrays of FIG. 7, a description will be made in the same manner as in the description of the first exemplary embodiment. FIGS. 8A and 8B are diagrams illustrating an example of multiple sets of drawing regions for which drawing is consecutively performed, set by set, using a sub array set, to perform drawing for a shot region. In FIGS. 8A and 8B, the same components as those in FIGS. 2, 3A, and 3B are denoted by the same reference symbols and the description thereof will not be repeated. First, for n1/n2=½, and at the same time n1=1 and n2=2 (see FIG. 8A), the number of sets of sub array drawing regions becomes n1+n2=3, the shifting amount becomes [1/n2=½] times the width CY. More specifically, by consecutively performing drawing using a sub array for three sets of sub array drawing regions that are shifted from one another by a half (½) of the width CY, uniform drawing over a shot region with a width GY can be achieved by multiple drawing (multiplicity=n2=2 (times)). In addition, for n1/n2=½, and at the same time n1=2 and n2=4 (see FIG. 8B), the number of sets of sub array drawing regions becomes n1+n2=6, and the shifting amount becomes [1/n2=¼] times the width CY. More specifically, by consecutively performing drawing using a sub array for four sets of sub array drawing regions that are shifted from one another by a quarter (¼) of the width CY, uniform drawing over a shot region with a width GY can be achieved by multiple drawing (multiplicity=n2=4 (times)). Furthermore, since the present exemplary embodiment uses multiple drawing (n2≧2) as the drawing, at an end portion of a shot region, there is generated a region 802, having a width which is ([1-1/n2] times the width CY), in which multiplicity (the number of times of multiple drawing) is insufficient (multiplicity is under n2 times). As for this region, by arranging a plurality of shot regions to be adjacent to each other on the substrate 122 and performing drawing consecutively, shot region by shot region, as in the form which is described above with reference to FIG. 4, the region can have the same multiplicity as other regions.

According to the present exemplary embodiment, it is possible to provide a drawing apparatus advantageous in effective use of a sub array of charged particle beams.

A method of manufacturing an article according to an exemplary embodiment of the invention is suitable for manufacturing an article such as a microdevice (for example, a semiconductor device), or a device having a microstructure. The manufacturing method includes a process (a process of performing drawing on a substrate) of forming a latent image pattern on a photosensitizing agent on a substrate that is coated with the photosensitizing agent using the drawing apparatus, and a process of developing the substrate with the latent image pattern formed in the drawing process. In addition, the manufacturing method may include other known processes (oxidation, film formation, deposition, doping, planarizing, etching, resist peeling, dicing, bonding, packaging). The method of manufacturing an article according to the present exemplary embodiment is advantageous over the related art manufacturing methods in terms of at least one of performance, quality, productivity, and production cost of articles.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-244366 filed Oct. 29, 2010, which is hereby incorporated by reference herein in its entirety.

What is claimed is:

1. A drawing apparatus that performs drawing on a substrate with an array of charged particle beams, the apparatus comprising:
a stage configured to hold the substrate;
a projection system configured to project the array onto the substrate held by the stage;
a driving mechanism configured to move at least one of the stage and the projection system relative to the other in a predetermined direction to change a drawing region on the substrate; and
a controller,
wherein the projection system is configured such that the array includes a plurality of sub arrays arranged discretely on the substrate with a space between the sub arrays in the predetermined direction, and a first width of the space in the predetermined direction is n1/n2 times (each of n1 and n2 is a positive integer) a second width of the sub array in the predetermined direction, and
wherein the controller is configured to control the projection system and the driving mechanism such that drawing is performed in order with the plurality of sub arrays for [n1+n2] sets of drawing regions that are shifted from one another by as much as [1/n2] times the first width so that drawing is performed for a shot region on the substrate.

2. The drawing apparatus according to claim 1, wherein n2is not less than 2, and
wherein the controller is configured to control the projection system and the driving mechanism such that n2 times of multiple drawing are performed with each of the plurality of sub arrays for the shot region.

3. The drawing apparatus according to claim 2, wherein the projection system is configured to satisfy n1/n2<1.

4. The drawing apparatus according to claim 1, wherein the predetermined direction corresponds to each of two directions orthogonal to each other.

5. The drawing apparatus according to claim 4, wherein the projection system is configured such that at least one of n1 and n2 with respect to one of the two directions is different from that of n1 and n2 with respect to the other of the two directions.

6. The drawing apparatus according to claim 1, wherein the controller is configured to control the projection system and the driving mechanism such that drawing is performed in order for a plurality of shot regions arranged to be adjacent to each other on the substrate.

7. The drawing apparatus according to claim 2, wherein the controller is configured to control the projection system and the driving mechanism such that drawing is performed in order for a plurality of shot regions arranged to be adjacent to each other on the substrate, and
wherein an arrangement of the plurality of shot regions is set for the substrate such that an end portion region of a shot region of which neighboring shot region does not exist and of which multiplicity of the multiple drawing is insufficient does not overlap an effective region which is set for the substrate.

8. A method of manufacturing an article, the method comprising:
performing drawing on a substrate using a drawing apparatus defined in claim 1;
developing the substrate on which the drawing has been performed; and
processing the developed substrate to manufacture the article.
